(19) United States
(12) Patent Application Publication
(10) Pub. No.: US 2010/0232338 A1
(43) Pub. Date: Sep. 16, 2010

(54) APPARATUS AND METHOD FOR PROVIDING VENUECAST SERVICES ON A NEXT GENERATION FORWARD LINK ONLY (FLO) NETWORK

(75) Inventor: RAGHURAMAN KRISHNAMOORTHI, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/722,331

(22) Filed: Mar. 11, 2010

Related U.S. Application Data
(60) Provisional application No. 61/160,017, filed on Mar. 13, 2009.

(51) Int. Cl. H04H 20/71; G06F 11/10; H03M 13/27

(52) U.S. Cl. 370/312; 714/752; 714/E11.032

(57) ABSTRACT

An apparatus and method for providing a coding scheme for interference cancellation in a broadcasting network comprising splitting a plurality of data packets into a plurality of M blocks, wherein each of the plurality of M blocks comprises a plurality of L packets; adding an outer code to each of the plurality of M blocks, wherein the outer code is applied to each of the plurality of L packets in each of the plurality of M blocks; encoding each of the plurality of L packets which have been outer coded to generate a plurality of encoded L packets in each of the plurality of M blocks; and interleaving each of the plurality of encoded L packets to generate a plurality of interleaved encoded L packets in each of the plurality of M blocks.

### CLAIM OF PRIORITY UNDER 35 U.S.C. §119

The present application for patent claims priority to Provisional Application No. 61/160,017 entitled Venue-Cast Services Architecture filed Mar. 13, 2009, and assigned to the assignee hereof and hereby expressly incorporated by reference herein.

### FIELD

This disclosure relates generally to apparatus and methods for wireless broadcasting. More particularly, the disclosure relates to Forward Link Only (FLO) wireless network for venuecasting into specific locations.

### BACKGROUND

Wireless communication systems deliver various communication services to mobile users which are separated and/or moving from the fixed telecommunications infrastructure. Wireless systems typically use radio transmission technology to allow mobile user devices to access various base stations in a wireless communication network, often in a cellular geometry. The base stations, in turn, are connected to mobile switching centers which route connections to and from the mobile user devices to other users on different communications networks such as the public switched telephony network (PSTN), Internet, or the wireless network itself. In this manner, users that are away from fixed sites or are on the move may receive a variety of communication services such as voice telephony, paging, messaging, email, data transfers, video, Web browsing, etc.

Wireless users use a variety of communication protocols to share the scarce radio spectrum allocated for wireless communication services. One important physical layer protocol relates to the access technique a mobile user device employs to connect to the wireless communications network. Various access methods include frequency division multiple access (FDMA), time division multiple access (TDMA), code division multiple access (CDMA), and orthogonal frequency division multiplex (OFDM). OFDM is increasingly popular in terrestrial wireless communication systems because its multicarrier format mitigates multipath distortions while providing flexible capacity for user needs. OFDM utilizes a plurality of carriers spaced apart in the frequency domain such that data modulated on each carrier is orthogonal (and thus independent) to the others. OFDM has the advantage of being conveniently modulated and demodulated through very efficient Fast Fourier Transform (FFT) techniques in both the transmitter and receiver.

### SUMMARY

Disclosed is an apparatus and method for providing venuecast services on a Forward Link Only (FLO) network. According to one aspect, a method for providing a coding scheme for interference cancellation in a broadcasting network comprising splitting a plurality of data packets into a plurality of M blocks, wherein each of the plurality of M blocks comprises a plurality of L packets; adding an outer code to each of the plurality of M blocks, wherein the outer code is applied to each of the plurality of L packets in each of the plurality of M blocks; encoding each of the plurality of L packets which have been outer coded to generate a plurality of encoded L packets in each of the plurality of M blocks; and interleaving each of the plurality of encoded L packets to generate a plurality of interleaved encoded L packets in each of the plurality of M blocks.

According to another aspect, an apparatus for providing a coding scheme for interference cancellation in a broadcasting network comprising a processor and a memory, the memory containing program code executable by the processor for performing the following: splitting a plurality of data packets into a plurality of M blocks, wherein each of the plurality of M blocks comprises a plurality of L packets; adding an outer code to each of the plurality of M blocks, wherein the outer code is applied to each of the plurality of L packets in each of the plurality of M blocks; encoding each of the plurality of L packets which have been outer coded to generate a plurality of encoded L packets in each of the plurality of M blocks; and interleaving each of the plurality of encoded L packets to generate a plurality of interleaved encoded L packets in each of the plurality of M blocks.

According to another aspect, an apparatus for providing a coding scheme for interference cancellation in a broadcasting network comprising means for splitting a plurality of data packets into a plurality of M blocks, wherein each of the plurality of M blocks comprises a plurality of L packets; means for adding an outer code to each of the plurality of M blocks, wherein the outer code is applied to each of the plurality of L packets in each of the plurality of M blocks; means for encoding each of the plurality of L packets which have been outer coded to generate a plurality of encoded L packets in each of the plurality of M blocks; and means for interleaving each of the plurality of encoded L packets to generate a plurality of interleaved encoded L packets in each of the plurality of M blocks.

According to another aspect, a computer-readable medium storing a computer program, wherein execution of the computer program is for splitting a plurality of data packets into a plurality of M blocks, wherein each of the plurality of M blocks comprises a plurality of L packets; adding an outer code to each of the plurality of M blocks, wherein the outer code is applied to each of the plurality of L packets in each of the plurality of M blocks; encoding each of the plurality of L packets which have been outer coded to generate a plurality of encoded L packets in each of the plurality of M blocks; and interleaving each of the plurality of encoded L packets to generate a plurality of interleaved encoded L packets in each of the plurality of M blocks.

Advantages of the present disclosure include efficient implementation of interference cancellation in a FLO network. In one aspect, this is achieved by defining a coding scheme which supports venuecast applications such that independent decoding is possible for each slot group in a superframe.

It is understood that other aspects will become readily apparent to those skilled in the art from the following detailed description, wherein it is shown and described various aspects by way of illustration. The drawings and detailed description are to be regarded as illustrative in nature and not as restrictive.

### BRIEF DESCRIPTION OF THE DRAWINGS

FIG. 1 is a block diagram illustrating an example access node/user equipment (UE) system.

FIG. 2 illustrates an example of a wireless communications system that supports a plurality of users.

FIG. 3 illustrates an example wireless broadcasting system which incorporates in-band venue services.

FIG. 4 illustrates an example transmission format of a mobile broadcasting service which uses orthogonal frequency division multiplex (OFDM).

FIG. 5 illustrates an example transmission format of a mobile broadcasting service which uses orthogonal frequency division multiplex (OFDM) where venue area broadcast services are transmitted in the portion of the superframe where scrambled pilots are typically scheduled for macro network usage.

FIG. 6 illustrates an example FLO superframe structure of 1 second duration showing the interleaving of wide-area, local-area, and venue-area pilots and data in the time domain.

FIG. 7 illustrates an example MediaFLO coverage scenario with two wide-areas and four local-areas.

FIG. 8 illustrates an example venuecast framing structure.

FIG. 9 illustrates examples of interference cancellation issues in an example FLO signal format where OFDM symbols are shown in the horizontal direction and frequency domain slots are shown in the vertical direction.

FIG. 10 illustrates an example coding scheme for interference cancellation in a wireless broadcasting system.

FIG. 11 illustrates an example code word numerology chart for venuecast support in a FLO system with a four frame codeword.

FIG. 12 illustrates an example high level overview of a concatenated coding scheme.

FIG. 13 illustrates an example transmission scheme in accordance with the present disclosure.

FIG. 14 illustrates another aspect of the example transmission scheme of FIG. 13.

FIG. 15 illustrate an example transmission order with 2 blocks.

FIG. 16 illustrates an example flow diagram of a coding scheme for efficient interference cancellation in a broadcasting network.

FIG. 17 illustrates an example of a device comprising a processor in communication with a memory for executing the processes for providing a coding scheme for efficient interference cancellation in a broadcasting network.

FIG. 18 illustrates an example of a device suitable for providing a coding scheme for efficient interference cancellation in a broadcasting network.

### DETAILED DESCRIPTION

The detailed description set forth below in connection with the appended drawings is intended as a description of various aspects of the present disclosure and is not intended to represent the only aspects in which the present disclosure may be practiced. Each aspect described in this disclosure is provided merely as an example or illustration of the present disclosure, and should not necessarily be construed as preferred or advantageous over other aspects. The detailed description includes specific details for the purpose of providing a thorough understanding of the present disclosure. However, it will be apparent to those skilled in the art that the present disclosure may be practiced without these specific details. In some instances, well-known structures and devices are shown in block diagram form in order to avoid obscuring the concepts of the present disclosure. Acronyms and other descriptive terminology may be used merely for convenience and clarity and are not intended to limit the scope of the present disclosure.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

The techniques described herein may be used for various wireless communication networks such as Code Division Multiple Access (CDMA) networks, Time Division Multiple Access (TDMA) networks, Frequency Division Multiple Access (FDMA) networks, Orthogonal FDMA (OFDMA) networks, Single-Carrier FDMA (SC-FDMA) networks, etc. The terms “networks” and “systems” are often used interchangeably. A CDMA network may implement a radio technology such as Universal Terrestrial Radio Access (UTRA), cdma2000, etc. UTRA includes Wideband-CDMA (W-CDMA) and Low Chip Rate (LCR). Cdma2000 covers IS-2000, IS-95 and IS-856 standards. A TDMA network may implement a radio technology such as Global System for Mobile Communications (GSM). An OFDMA network may implement a radio technology such as Evolved UTRA (E-UTRA), IEEE 802.11, IEEE 802.16, IEEE 802.20, Flash-OFDM®, etc. UTRA, E-UTRA, and GSM are part of Universal Mobile Telecommunication System (UMTS). Long Term Evolution (LTE) is an upcoming release of UMTS that uses E-UTRA. UTRA, E-UTRA, GSM, UMTS and LTE are described in documents from an organization named “3rd Generation Partnership Project” (3GPP). cdma2000 is described in documents from an organization named “3rd Generation Partnership Project 2” (3GPP2). These various radio technologies and standards are known in the art.

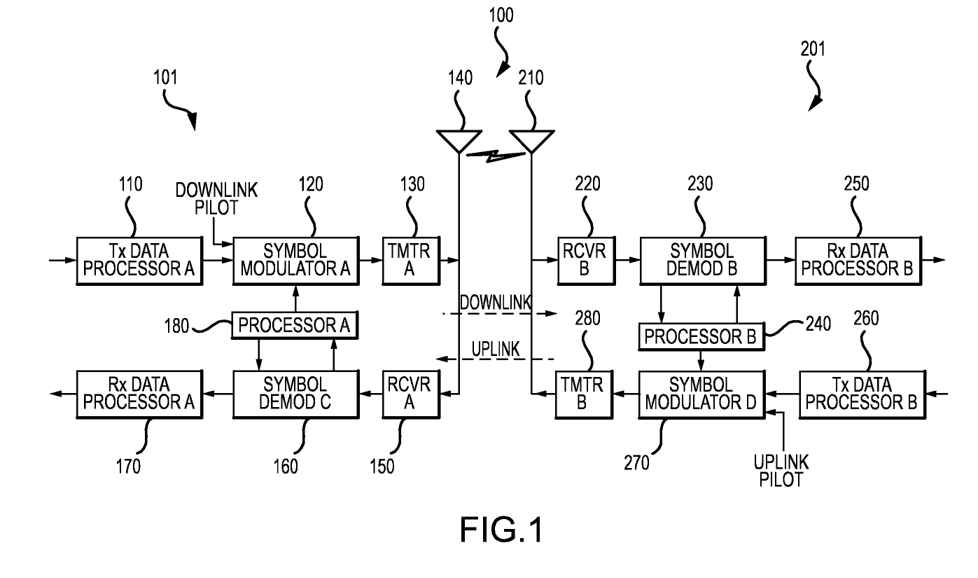

FIG. 1 is a block diagram illustrating an example access node/user equipment (UE) system 100. One skilled in the art would understand that the example access node/UE system 100 illustrated in FIG. 1 may be implemented in an FDMA environment, an OFDMA environment, a CDMA environment, a WCDMA environment, a TDMA environment, a SDMA environment or any other suitable wireless environment.

The access node/UE system 100 includes an access node 101 (e.g., base station, macro transmitter, venue transmitter) and a user equipment or UE 201 (e.g., wireless communication device, receiving device). In the downlink leg, the access node 101 includes a transmit (TX) data processor A 110 that accepts, formats, codes, interleaves and modulates (or symbol maps) traffic data and provides modulation symbols (e.g., data symbols). The TX data processor A 110 is in communication with a symbol modulator A 120. The symbol modulator A 120 accepts and processes the data symbols and downlink pilot symbols and provides a stream of symbols. In one aspect, it is the symbol modulator A 120 that modulates (or symbol maps) traffic data and provides modulation symbols (e.g., data symbols). In one aspect, symbol modulator A 120 is in communication with processor A 180 which provides configuration information. Symbol modulator A 120 is in communication with a transmitter unit (TMTR) A 130. The symbol modulator A 120 multiplexes the data symbols and downlink pilot symbols and provides them to the transmitter unit A 130.

Each symbol to be transmitted may be a data symbol, a downlink pilot symbol or a signal value of zero. The downlink pilot symbols may be sent continuously in each symbol period. In one aspect, the downlink pilot symbols are frequency division multiplexed (FDM). In another aspect, the downlink pilot symbols are orthogonal frequency division multiplexed (OFDM). In yet another aspect, the downlink pilot symbols are code division multiplexed (CDM). In one aspect, the transmitter unit A 130 receives and converts the stream of symbols into one or more analog signals and further conditions, for example, amplifies, filters and/or frequency upconverts the analog signals, to generate an analog downlink signal suitable for wireless transmission. The analog downlink signal is then transmitted through antenna 140.

In the downlink leg, the UE 201 (e.g., wireless communication device, receiving device) includes antenna 210 for receiving the analog downlink signal and inputting the analog downlink signal to a receiver unit (RCVR) B 220. In one aspect, the receiver unit B 220 conditions, for example, filters, amplifies, and frequency downconverts the analog downlink signal to a first “conditioned” signal. The first “conditioned” signal is then sampled. The receiver unit B 220 is in communication with a symbol demodulator B 230. The symbol demodulator B 230 demodulates the first “conditioned” and “sampled” signal (e.g., data symbols) outputted from the receiver unit B 220. One skilled in the art would understand that an alternative is to implement the sampling process in the symbol demodulator B 230. The symbol demodulator B 230 is in communication with a processor B 240. Processor B 240 receives downlink pilot symbols from symbol demodulator B 230 and performs channel estimation on the downlink pilot symbols. In one aspect, the channel estimation is the process of characterizing the current propagation environment. The symbol demodulator B 230 receives a frequency response estimate for the downlink leg from processor B 240. The symbol demodulator B 230 performs data demodulation on the data symbols to obtain data symbol estimates on the downlink path. The data symbol estimates on the downlink path are estimates of the data symbols that were transmitted. The symbol demodulator B 230 is also in communication with a RX data processor B 250.

The RX data processor B 250 receives the data symbol estimates on the downlink path from the symbol demodulator B 230 and, for example, demodulates (i.e., symbol demaps), deinterleaves and/or decodes the data symbol estimates on the downlink path to recover the traffic data. In one aspect, the processing by the symbol demodulator B 230 and the RX data processor B 250 is complementary to the processing by the symbol modulator A 120 and TX data processor A 110, respectively.

In the uplink leg, the UE 201 includes a TX data processor B 260. The TX data processor B 260 accepts and processes traffic data to output data symbols. The TX data processor B 260 is in communication with a symbol modulator D 270. The symbol modulator D 270 accepts and multiplexes the data symbols with uplink pilot symbols, performs modulation and provides a stream of symbols. In one aspect, symbol modulator D 270 is in communication with processor B 240 which provides configuration information. The symbol modulator D 270 is in communication with a transmitter unit B 280. In a forward link only (FLO) system, there is no uplink leg since the direction of the broadcast is from the access node 101 (e.g., base station, macro transmitter, venue transmitter) to the UE 201 (e.g., wireless communication device, receiving device). However, a communication system may include a FLO component plus a return link with multiple access capabilities, i.e., the uplink leg as disclosed herein.

Each symbol to be transmitted may be a data symbol, an uplink pilot symbol or a signal value of zero. The uplink pilot symbols may be sent continuously in each symbol period. In one aspect, the uplink pilot symbols are frequency division multiplexed (FDM). In another aspect, the uplink pilot symbols are orthogonal frequency division multiplexed (OFDM). In yet another aspect, the uplink pilot symbols are code division multiplexed (CDM). In one aspect, the transmitter unit B 280 receives and converts the stream of symbols into one or more analog signals and further conditions, for example, amplifies, filters and/or frequency upconverts the analog signals, to generate an analog uplink signal suitable for wireless transmission. The analog uplink signal is then transmitted through antenna 210.

The analog uplink signal from UE 201 is received by antenna 140 and processed by a receiver unit A 150 to obtain samples. In one aspect, the receiver unit A 150 conditions, for example, filters, amplifies and frequency downconverts the analog uplink signal to a second “conditioned” signal. The second “conditioned” signal is then sampled. The receiver unit A 150 is in communication with a symbol demodulator C 160. One skilled in the art would understand that an alternative is to implement the sampling process in the symbol demodulator C 160. The symbol demodulator C 160 performs data demodulation on the data symbols to obtain data symbol estimates on the uplink path and then provides the uplink pilot symbols and the data symbol estimates on the uplink path to the RX data processor A 170. The data symbol estimates on the uplink path are estimates of the data symbols that were transmitted. The RX data processor A 170 processes the data symbol estimates on the uplink path to recover the traffic data transmitted by the wireless communication device 201. The symbol demodulator C 160 is also in communication with processor A 180. Processor A 180 performs channel estimation for each active terminal transmitting on the uplink leg. In one aspect, multiple terminals may transmit pilot symbols concurrently on the uplink leg on their respective assigned sets of pilot subbands where the pilot subband sets may be interlaced.

Processor A 180 and processor B 240 direct (i.e., control, coordinate or manage, etc.) operation at the access node 101 (e.g., base station) and at the UE 201, respectively. In one aspect, either or both processor A 180 and processor B 240 are associated with one or more memory units (not shown) for storing of program codes and/or data. In one aspect, either or both processor A 180 or processor B 240 or both perform computations to derive frequency and impulse response estimates for the uplink leg and downlink leg, respectively.

In one aspect, the access node/UE system 100 is a multiple-access system. For a multiple-access system (e.g., frequency division multiple access (FDMA), orthogonal frequency division multiple access (OFDMA), code division multiple access (CDMA), time division multiple access (TDMA), space division multiple access (SDMA), etc.), multiple terminals transmit concurrently on the uplink leg, allowing access to a plurality of UEs. In one aspect, for the multiple-access system, the pilot subbands may be shared among different terminals. Channel estimation techniques are used in cases where the pilot subbands for each terminal span the entire operating band (possibly except for the band edges). Such a pilot subband structure is desirable to obtain frequency diversity for each terminal.

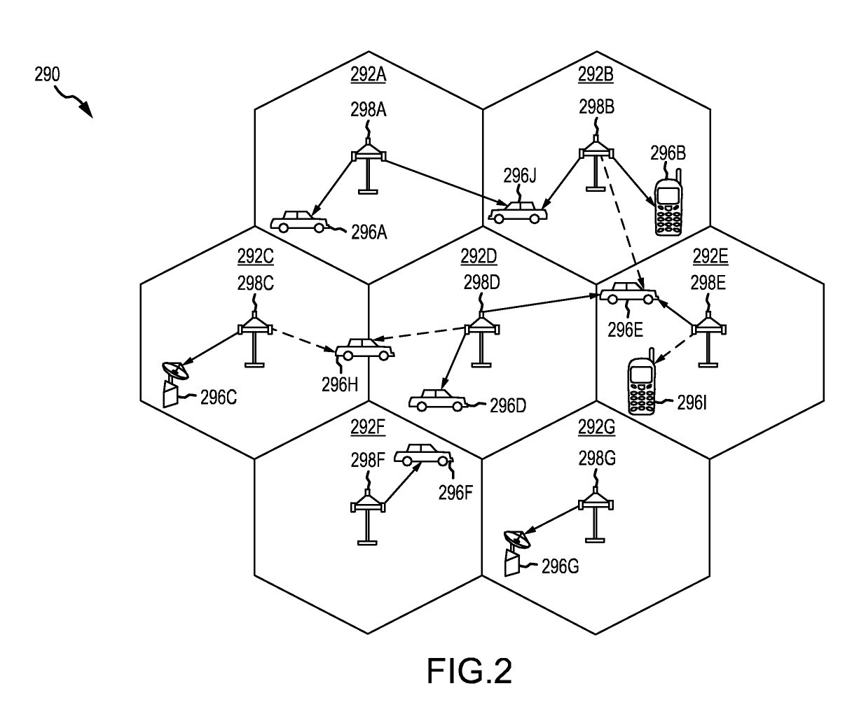

FIG. 2 illustrates an example of a wireless communications system 290 that supports a plurality of users (e.g., mobile user devices 296B, 296I). In FIG. 2a, reference numerals 292A to 292G refer to cells, reference numerals 298A to 298G refer to base stations (BS) or base transceiver station (BTS) and reference numerals 296A to 296J refer to access User Equipments (UE) or mobile user devices. Cell size may vary. Any of a variety of algorithms and methods may be used to schedule transmissions in system 290. System 290 provides communication for a number of cells 292A through 292G, each of which is serviced by a corresponding base station 298A through 298G, respectively.

In one example, a wireless communication system provides mobile broadcasting services to mobile user devices. Broadcasting is a transmission method from one transmitter to many receivers simultaneously in a coverage area. One example of a mobile broadcasting standard is known as FLO (Forward Link Only). In one aspect, the FLO physical layer employs OFDM with 4096 carriers over the system bandwidth, with a much higher data capacity than other systems. Mobile broadcasting services include real-time video and audio streams, non-real time video and audio clips, data content, etc. In one example, the FLO OFDM symbol time is 833.33 microseconds, comprised of 738.02 μs of bearer traffic, 3.06 μs of window, and 92.25 μs of cyclic prefix. A cyclic prefix is a repetition of the end of an OFDM symbol at the beginning of the next OFDM symbol to mitigate multipath interference.

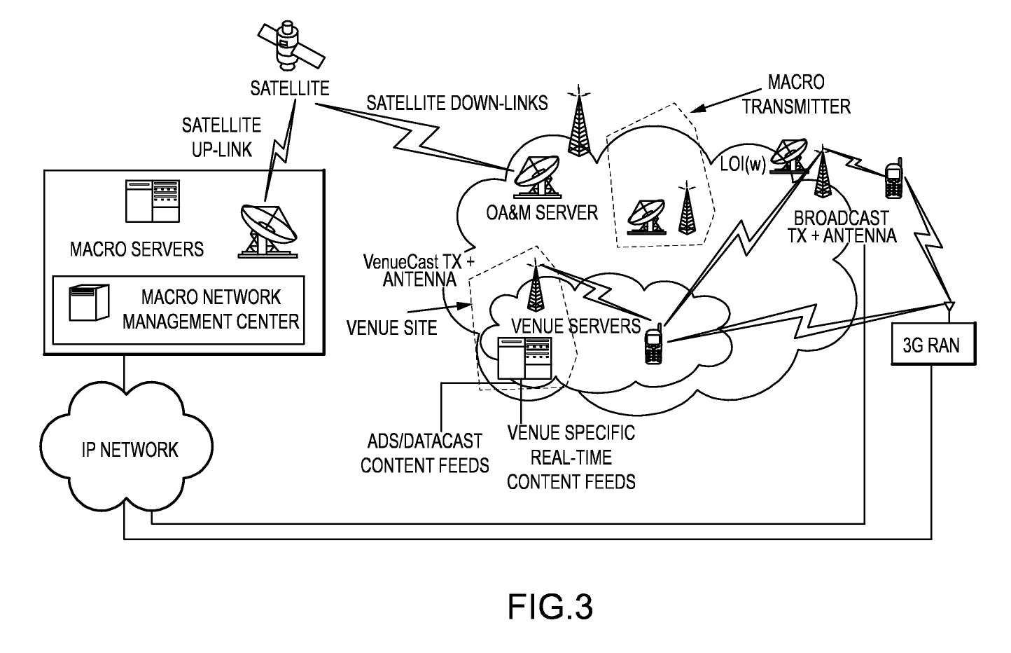

FIG. 3 illustrates an example wireless broadcasting system which incorporates in-band venue services. Shown in the service coverage area is a venue site which contains a venue transmitter and antenna and venue servers to provide venue-cast contents or other contents, such as advertisements, datacasts, etc. In addition, the service coverage area includes one or more macro transmitters and antennas to broadcast macro-cast contents. Also illustrated is a macro network management center for managing the macro services and the macro-cast contents. In one aspect, the macro network management center is connected to a third generation wireless radio access network (3G RAN) via an Internet Protocol (IP) network.

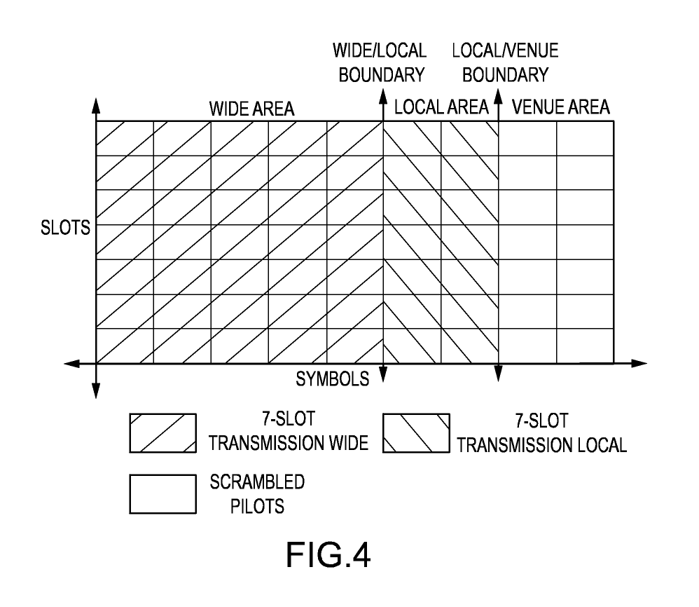

FIG. 4 illustrates an example transmission format of a mobile broadcasting service which uses orthogonal frequency division multiplex (OFDM). The format shows symbols, in the time domain, along the horizontal axis and slots, in the frequency domain, along the vertical axis. As illustrated in FIG. 4, the symbols refer to OFDM symbols in time and the slots refer to groups of subcarriers in frequency. As a multiplexing technique, different services may be simultaneously broadcast using different groups of symbols and slots.

For example, FIG. 4 shows a multiplexing arrangement with 9 symbols per superframe where the first five symbols are dedicated for wide area services, the next two symbols are used for local area services, and the last two symbols are used for scrambled pilots. In one aspect, venue area services may be introduced into the symbol space normally used for scrambled pilots. The combination of wide area services and local area services may be referred as macro network services (“macro services”), while the venue area services (“venue services”) are intended only for a specific venue. In this arrangement, the macro service receiving devices use only a portion of the frame. Since the macro service receiving devices decode only macro service data, existing (i.e., legacy) macro receiving devices do not process data from the venue service portion of the frame. In one aspect, the macro services are broadcast by a macro transmitter while the venue services are broadcast by a venue transmitter. In one example, the power level of the macro transmitter is higher at the symbol spaces for the macro services than the symbol spaces for the venue services.

Delivery of services to specific venue areas (i.e., venue services) increases efficiency in reaching targeted audience, and as such, increases business value of the broadcast. For example, electronic coupons can be broadcast (i.e., sent) to receiving devices of potential shoppers in a defined venue location. In another example, streaming videos can introduce amenities available in a shopping mall. In another example, advertisements from different vendors can be broadcast to attendees at a convention center. One skilled in the art would understand that the examples given here are not an exclusive listing.

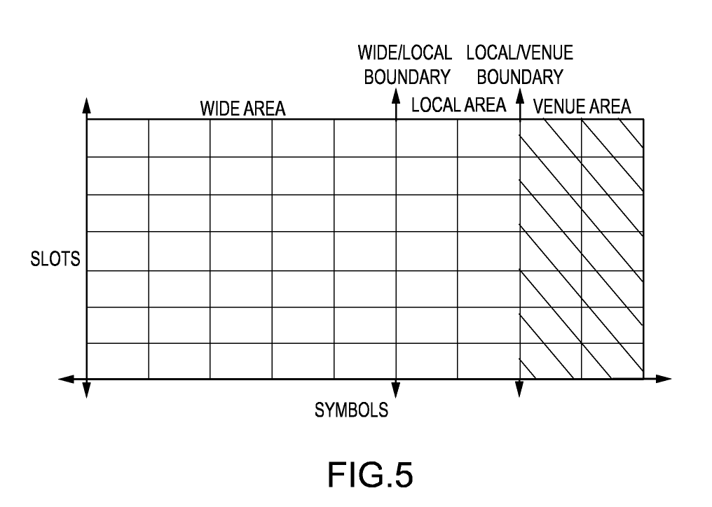

FIG. 5 illustrates an example transmission format of a mobile broadcasting service which uses orthogonal frequency division multiplex (OFDM) where venue services are transmitted in the portion of the superframe where scrambled pilots are typically scheduled for usage with the macro services. In one aspect, a venue transmitter is placed at the desired venue site to broadcast venuecast contents. A given receiving device at the venue site would receive the macro-cast contents from a macro transmitter and the venuecast contents from the venue transmitter in the same frequency band. Since the venuecast contents are broadcast in the portion of the superframe where scrambled pilots are typically scheduled, the receiving device includes the ability to decode the venuecast contents without pilots.

FIGS. 4 and 5 illustrate the partition between the portions of the superframe dedicated for macro network services (i.e., wide area services and local area services) and for venue area services. Essentially, a fraction of the OFDM data symbols are blanked out from the broadcasted waveform from the macro-cast transmitter (“macro waveform”) which are then filled by transmissions from the venue transmitter for venuecast content.

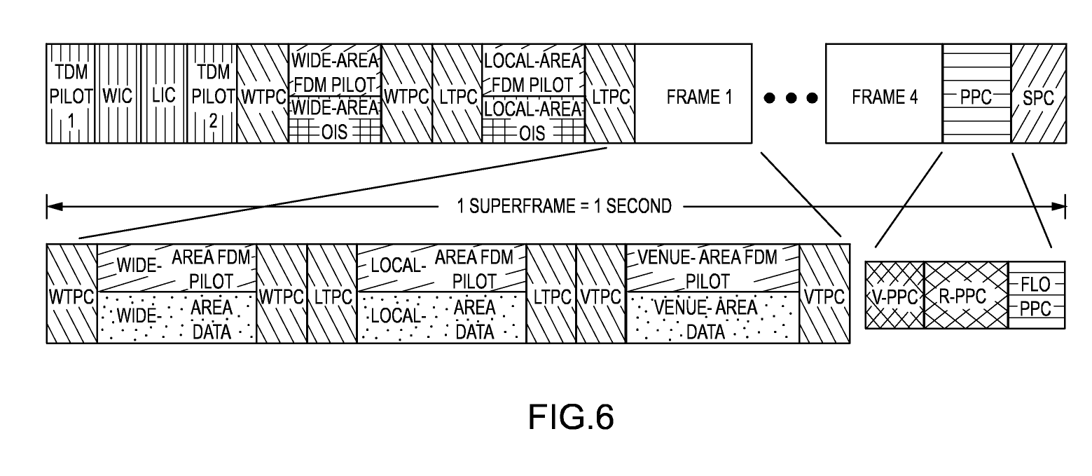

FIG. 6 illustrates an example FLO superframe structure of 1 second duration showing the interleaving of wide-area, local-area, and venue-area pilots, and wide-area, local-area, and venue-area data in the time domain. In one example, interference cancellation is performed at the physical layer of a network protocol stack to ensure that macro transmitters which are higher power are not turned off, while the venue transmitters which are lower power are turned on and off as needed. In one example, the macro transmitters send a predetermined (i.e., known) pattern, designated as scrambled pilots, during the venue portion of the frame. In one aspect, the predetermined pattern includes a position pilot channel (PPC) which can be used for determining the absence or presence of venuecast contents. In one example, the position pilot channel is divided into two parts: a network position pilot channel (NETWORK-PPC) and a venue position pilot channel (VENUE-PPC). The VENUE-PPC portion is dedicated for venue transmitters and is further sub-divided into two parts (V-PPC and R-PPC):
V-PPC: The V-PPC symbol is dedicated for transmission of venue transmitter identification and is used to determine the scrambling sequence used for venue transmission and the presence or absence of venue-cast contents.
R-PPC: The R-PPC symbols are used for transmitting venue overhead information and contain information identifying the starting point of the venue service portion (i.e., symbol space) in the superframe.

In addition, the venue signal may contain transition signals, known as V-TPC, as shown in FIG. 6, which aid in the convergence of the automatic gain control (AGC) loops in the receiver and to bootstrap the channel estimation. In one example, the V-TPC signals are present at the beginning and end of the venue portion of each frame.

In one example, the macro transmitters operate in inactive PPC mode during the VENUE-PPC symbol transmission period. To receive venuecast contents, receiving devices determine the presence of venue using the V-PPC symbol and obtain venue overhead information and control information using the R-PPC symbols. In this example, only the macro transmitter transmits the synchronization pilots (TDM1 and TDM2). The macro transmitter requires no changes for supporting venue services. In one example, the macro signal power may be reduced during the venue portion of the frame. In one aspect, it may not be possible to turn the macro transmitters off and on, but reducing their transmitted power level may be feasible.

In one example, to decode the venue signal, the receiving devices needs to support pilot interference cancellation on the venue portion of the frame and independent scrambling of the wide, local, and venue portions of the frame. Many techniques for pilot interference cancellation are well known in the art and can be used in conjunction with the present disclosure without affecting its scope or intent.

In one aspect, in order for the receiving device to detect venuecast transmission efficiently in the presence of macro-cast transmission, venue overhead information symbols that identify venuecast transmission position and characteristics are included in the superframe. In one example, the venue overhead information symbol is included with the venuecast contents.

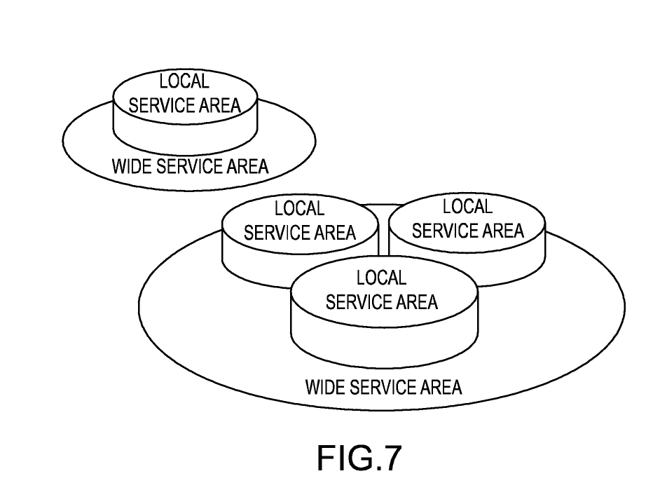

In one aspect, the MediaFLO wireless system was designed to support transmission of services targeted for two different coverage areas within a single RF channel: wide-area services, covering multiple markets (e.g. metropolitan areas) and local-area services, covering a single market. For example, FIG. 7 illustrates an example MediaFLO coverage scenario with two wide-areas and four local-areas.

In one example, FLO services are currently used to broadcast information to mobile users over large areas, with a typical local area minimum granularity corresponding to a city. However, in one aspect, the current FLO standard does not allow for location based services to users since channels are broadcast over at least a local area. FLO network deployment requires installation of transmitters with backhaul support for receiving wide and local feeds, which requires a centralized network operation center (NOC) for content preparation.

In one aspect, service providers desire an increase in overall capacity of a FLO network by allowing for location specific channels without degrading existing coverage. For example, FLO deployment may be increased by encouraging FLO “hotspots” which offer location specific content and provide a new market opportunity by offering location specific advertising using FLO.

In another aspect, current FLO networks have coverage holes at the boundary of wide and local areas where receivers treat local interference as noise. Service providers desire enhanced FLO receivers to exploit the structure of FLO interference to have better coverage for local and wide areas at coverage boundaries.

Some examples of possible applications of location based service are:
Location specific advertising: FLO users can receive advertisements of interest when they are near a specific location, e.g. coupons for restaurants, sales information at nearby stores, etc.
Location specific channels: flight information at airports, event information at theme parks, fairs, etc.
Extra services at hotspots: additional channels available in select areas
Enhanced coverage for local channels

In one example, there are several service requirements for a venuecast. Coverage over a small area must be provided. For example, the venuecast service should support transmission of services for reception within a venue, e.g., stadium, race track, mall, casino, etc. For example, there should be minimal degradation to existing FLO services, and there should be support of at least 1 Mbps capacity of the venue area. In one example, a spectral efficiency of about 0.4 bits/sec per Hz is targeted, which yields a capacity of approximately 1.768 Mbps over the venue area.

In one example, superposition coding may be used in a venuecast service along with existing wide/local service. In one aspect, the superposition waveform power is chosen low enough to not affect the FLO signal coverage. Superposition coding is a coding technique which sends independent packets of data in parallel to multiple receivers.

In one aspect, receivers for decoding superposition coded signals rely on interference cancellation by the following generic steps: First, decode a stronger signal. Second, cancel the stronger signal first to decode a weaker signal. For example, the signal of each received subcarrier may be expressed as:

Y=H₁X₁+H₂X₂+W (local interference)

Y=H_{F}X_{F}+H_{V}(aX_{F}+bX_{V})+W (venuecast)

where X_{F} is the FLO signal, X_{V} is the venue signal and W is additive noise. In one example, the scaling parameters a,b are selected such that the venuecast signal does not affect FLO signal coverage. In one aspect, venuecast receivers first decode X_{F} and then obtain X_{V} as X_{F} may have a higher signal strength than X_{V}. In another aspect, for local interference cancellation, either X₁ or X₂ may have higher signal strength. In one example, the receiver determines the order of interference cancellation dynamically.

In one example, a venuecast waveform is sent as a superposition waveform to the FLO waveform. Key features of the venuecast waveform may include:
Modulation type: quarternary phase shift keying (QPSK)
Waveform parameters (FFT size, cyclic prefix (CP) length, slot to interlace map, frame length): identical to FLO waveform
Scrambling: use the same 20 bit scrambler as FLO, with the reserved bit (b0) set to 1. For the pilot signal, scrambling options vary depending on venuecast type
Service availability: signaled using the Pilot Positioning Channel (PPC), to convey the type of venuecast service and energy ratio
Overhead signaling: superposed on both wide and local Overhead Information Symbols (OIS)

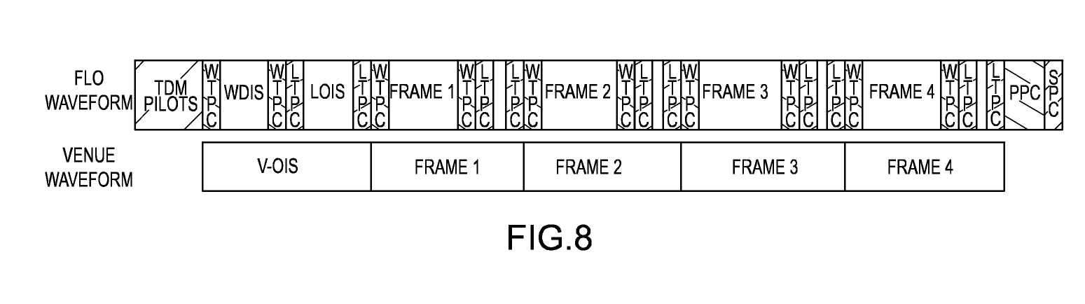

FIG. 8 illustrates an example venuecast framing structure. FIG. 8 shows a FLO waveform with four frames and overhead fields and a venue waveform with a venue OIS (V-OIS) field and four frames. Note that the PPC of the FLO waveform may be modified to contain information on availability of venuecast service.

In one example, a venuecast pilot is scrambled identically as venuecast data such that it appears as noise to a FLO pilot. For example, channel estimation of venuecast data can take advantage of interference cancellation by first estimating the FLO channel, thresholding and converting the data to the frequency domain for interference cancellation, and then obtaining venuecast channel estimates by descrambling and IFFT processing of interference cancelled channel observations.

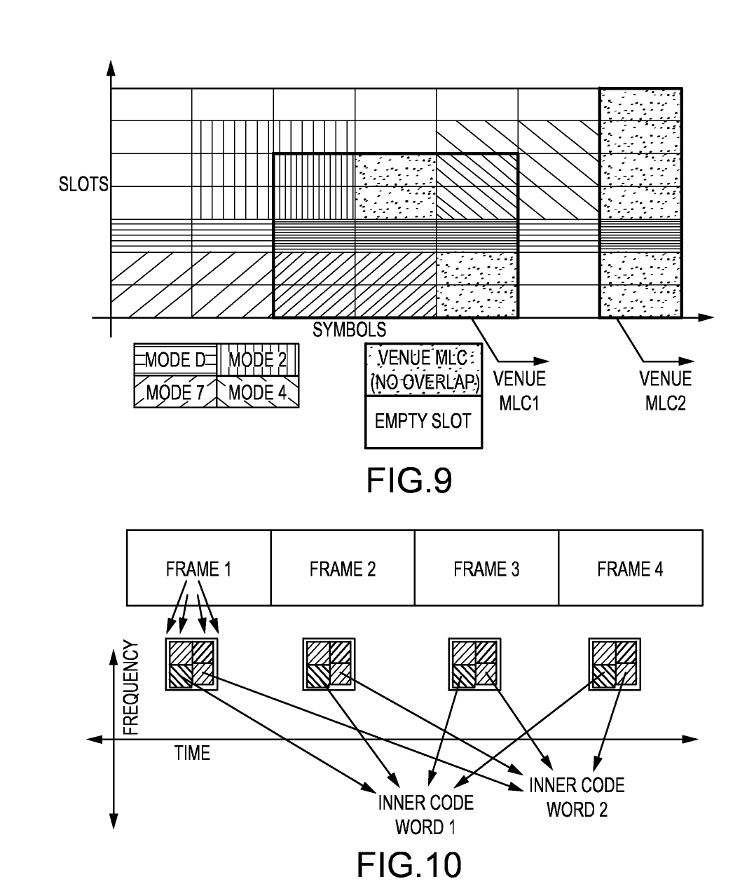

FIG. 9 illustrates examples of interference cancellation issues in a conventional example FLO signal format where OFDM symbols are shown in the horizontal direction and frequency domain slots are shown in the vertical direction. High receiver complexity is required in this conventional example for actual interference cancellation which is not practical for actual implementation. For example, to decode one venue MediaFLO Logical Channel (MLC), specific code blocks from multiple FLO MLCs may need to be decoded. Also, the receiver may need to wakeup earlier than the venue MLC to receive FLO data, which may be complicated to determine. The complexity may be as high as two turbo decoders per slot. Re-encoding of FLO data only may be required to cancel slots of interest.

In one aspect, venuecast and local interference cancellation for a next generation broadcasting system may be designed to overcome the limitations of a current broadcasting system. For example, current receivers may not exploit the structure of venuecast information. In one aspect, the coding scheme may be changed to benefit venuecast by determining a coding scheme with the following constraints:
Coding across frames to capture better time diversity
“Local” decidability for interference cancellation requires knowledge only of FLO mode on slot of interest to do interference cancellation and cannot have multiple slots corresponding to one codeword at a time
With a 4 frame structure, codeword size is fixed to be 4 slots

FIG. 10 illustrates an example coding scheme for interference cancellation in a wireless broadcasting system. FIG. 10 shows four example code blocks from each frame, where the first code block from the four frames are assigned as inner code word 1, the second code block from the four frames are assigned as inner code word 2, etc.

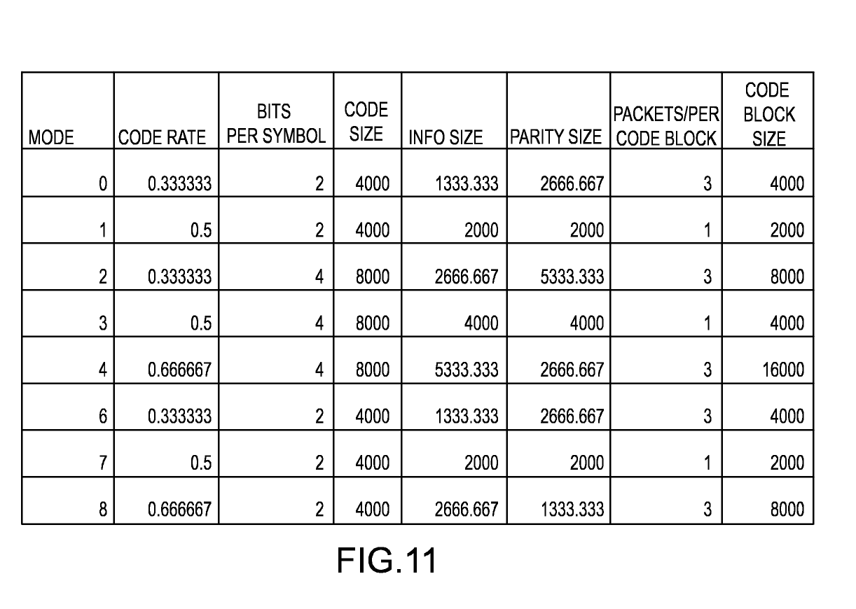

FIG. 11 illustrates an example code word numerology chart for venuecast support in a FLO system with a four frame codeword. Shown in FIG. 11 are nine different modes with different code rates, bits per symbol, code size, information size, parity bit size, packets per code block, and code block size. In one aspect, advantages of this coding include that it enables venuecast services, enables local interference cancellation, and provides a lower granularity at the physical layer which saves, for example, about 2% in capacity for video channels (assuming mode 2 is used for video). However, the disadvantages are that it does not capture time diversity in a frame and it uses multiple interleaver sizes for the turbo encoder and decoder.

In another aspect, a coding scheme for interference cancellation may be obtained by extending the previous scheme by adding an outer code. In one example, an inner code is a turbo code that spans exactly one slot per frame so that there are four frames in a superframe. In another example, an outer code is a single parity check code that encodes across the turbo code words. In one aspect, for capturing time diversity in an efficient manner, the turbo packets are divided into M groups, each containing L packets. Packets may be sent one per group in a round robin manner such that each packet has a different transmission order to maximize time diversity. For each group, a parity packet is computed such that the effective system rate is M/(M+1). In one example, the rate loss due to the additional parity packet may be traded off for better time diversity.

In one example, the transmission scheme may be provided with the following structure.
First, split N transmission data packets into M blocks, each containing L packets:
   Block 0 contains [0, M, 2M, . . . (L−1)M]
   Block 1 contains [1, M+1, . . . (L−1)M+1]
   Block M−1 contains [M−1, 2M−1, . . . LM−1]
Next, for each block, compute a parity packet:
   Block 0 now contains [0, M, 2M, . . . (L−1)M, parity packet]
   A block now contains L+1 packets each
Finally, turbo encode all packets in each block

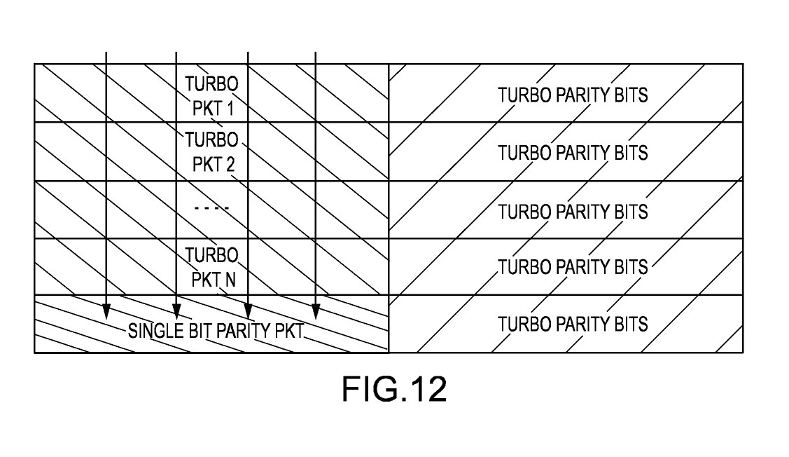

FIG. 12 illustrates an example high level overview of a concatenated coding scheme. Shown in FIG. 12 are an array of N turbo packets along with a single bit parity packet and several turbo parity bits.

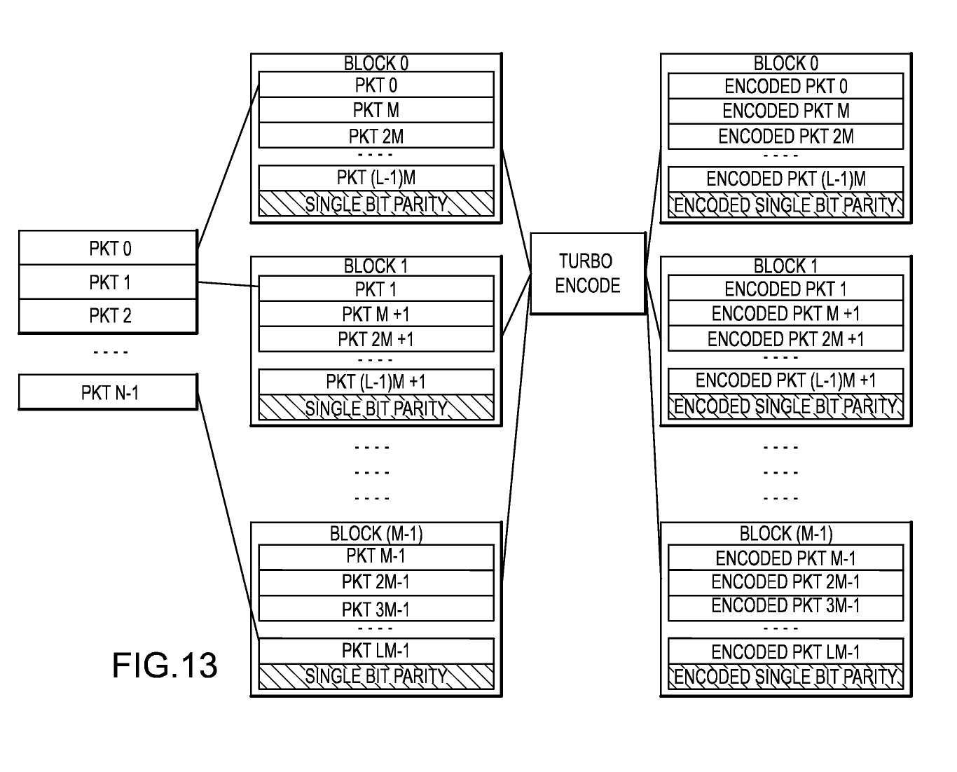

FIG. 13 illustrates an example transmission scheme in accordance with the present disclosure. FIG. 13 expands on the concatenated coding scheme by illustrating how data packets, labeled 0 through N+1, are divided into M blocks, with each block containing L data packets and a single bit parity packet. The M blocks are then fed into a turbo encoder which yields M turbo-encoded blocks, with each turbo-encoded block containing L encoded data packets and an encoded single bit parity packet.

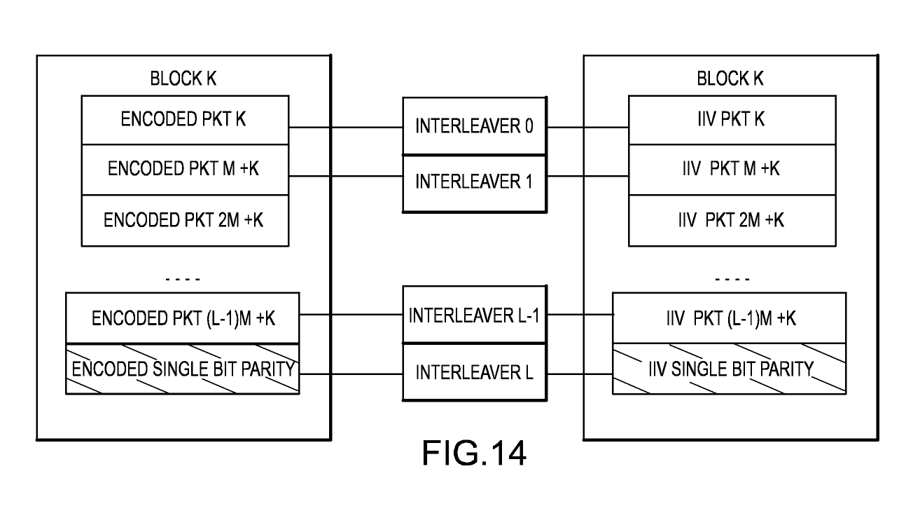

FIG. 14 illustrates another aspect of the example transmission scheme of FIG. 13. FIG. 14 further expands on the concatenated coding scheme by showing an example encoded block K consisting of L encoded data packets and an encoded single bit parity packet. The encoded data packets are sent to interleavers to generate an example interleaved block K consisting of L interleaved data packets and an interleaved single bit parity packet.

In one aspect, each encoded data packet is interleaved before transmission wherein each encoded data packet within a block passes through a different interleaver to maximize time diversity. In one example, there is no interleaving across blocks. To maximize time diversity, the data packets may be organized in the following manner:
Each frame contains ¼ of each data packet, known as a sub-packet
One sub-packet from each group is transmitted serially
   Slot 1 of frame 1 contains ¼ of packet 0 from block 0
   Slot 2 of frame 1 contains ¼ of packet 0 from block 1 . . .
   Slot N(L+1) of frame 1 contains ¼ of packet L of block M

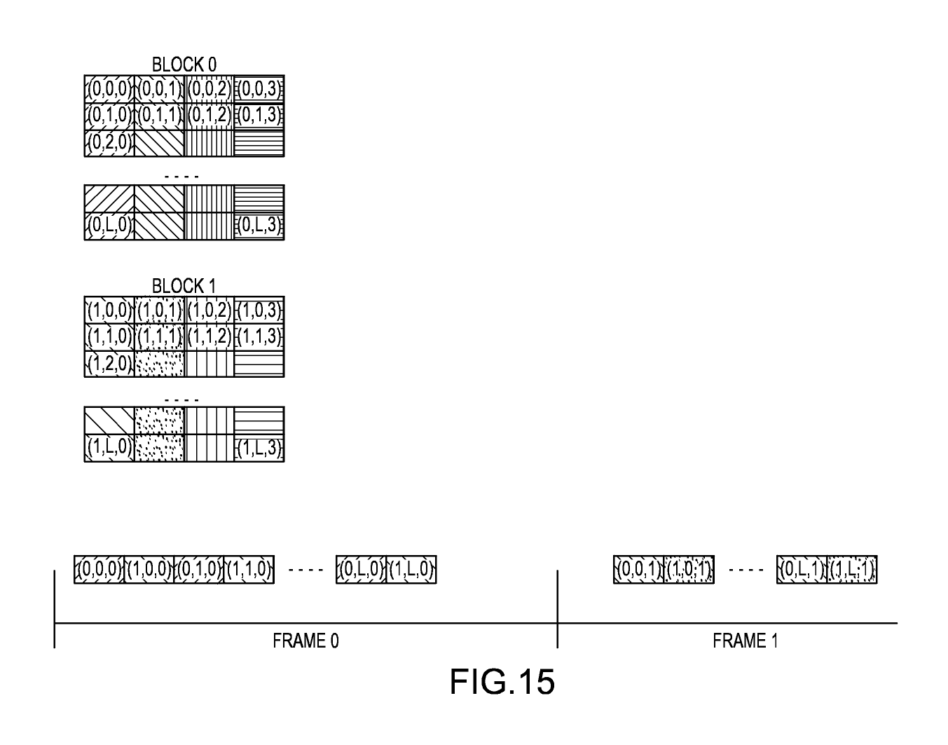

FIG. 15 illustrate an example transmission order with 2 blocks. Shown in FIG. 15 are the divisions of each data packet into four sub-packets which are inserted into different frames.

With the disclosed concatenated coding scheme, interference cancellation may be performed efficiently. For example, interference from the FLO signal only in the slots of interest may be removed in an efficient manner. For interference cancellation, only the inner code is needed. Since an inner codeword spans exactly four slots, it is possible to remove interference only in the slots of interest. In another example, for FLO signal decoding, the entire concatenated code is used.

The disclosed concatenated coding scheme may be extended in several ways. For example, instead of a turbo code, the inner code may be modified to be a low density parity check (LDPC) code or other block codes. For example, instead of a single parity check code, the outer code may be modified to be a Reed Solomon (RS) code or another block code. One skilled in the art would understand that the listed types of outer code are only examples and that other outer codes may be used without affecting the scope or spirit of the present disclosure.

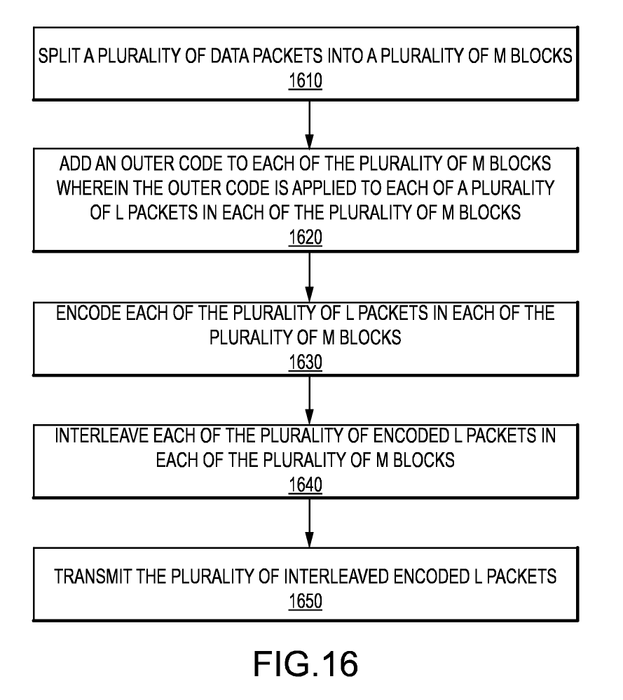

FIG. 16 illustrates an example flow diagram of a coding scheme for efficient interference cancellation in a broadcasting network. In one example, the broadcasting network includes one or more of the following coverage: wide area, local area or venue area. In block 1610, split a plurality of data packets into a plurality of M blocks. In one example, each of the plurality of M blocks contains a plurality of L packets. In one example, block 0 contains packets [0, M, 2M, . . . (L−1)M], block 1 contains packets [1, M+1, . . . (L−1)M+1], block M−1 contains packets [M−1, 2M−1, . . . LM−1], etc.

Following block 1610, in block 1620, add an outer code to each of the plurality of M blocks, wherein the outer code is applied to each of the plurality of L packets in each of the plurality of M blocks. In one example, the outer code is a single parity check code. In one example, block 0 now contains packets [0, M, 2M, . . . (L−1)M, parity] and each block now contains L+1 packets. In another example, the outer code is a Reed-Solomon code. In yet another example, the outer code is a block code.

Following block 1620, in block 1630, encode each of the plurality of L packets in each of the plurality of M blocks. In one example, turbo coding is used to encode the plurality of L packets in each of the plurality of M blocks. In another example, low density parity check (LDPC) code is used to encode the plurality of L packets in each of the plurality of M blocks. In yet another example, a block code is used to encode the plurality of L packets in each of the plurality of M blocks.

Following block 1630, in block 1640, interleave each of the plurality of encoded L packets in each of the plurality of M blocks. In one example, each of the plurality of encoded L packets in one of the M blocks passes through a different interleaver to maximize time diversity.

Following block 1640, in block 1650, transmit (i.e., broadcast) the plurality of interleaved encoded L packets, for example, to at least one mobile user device. In one example, each frame contains ¼ of each interleaved encoded L packet, known as a sub-packet. And, in one aspect, one sub-packet from each of the M blocks is transmitted serially. In one example, the plurality of interleaved encoded L packets are transmitted on a venuecast waverform. In one example, the venuecast waveform includes one or more of the following features: a QPSK modulation, at least one waveform parameter that is the same as that of a FLO waveform, scrambled bits, service availability signaling using position pilot channel (PPC), or overhead signal.

One skilled in the art would understand that the steps disclosed in the example flow diagram in FIG. 16 can be interchanged in their order without departing from the scope and spirit of the present disclosure. Also, one skilled in the art would understand that the steps illustrated in the flow diagram are not exclusive and other steps may be included or one or more of the steps in the example flow diagram may be deleted without affecting the scope and spirit of the present disclosure.

Those of skill would further appreciate that the various illustrative components, logical blocks, modules, circuits, and/or algorithm steps described in connection with the examples disclosed herein may be implemented as electronic hardware, firmware, computer software, or combinations thereof. To clearly illustrate this interchangeability of hardware, firmware and software, various illustrative components, blocks, modules, circuits, and/or algorithm steps have been described above generally in terms of their functionality. Whether such functionality is implemented as hardware, firmware or software depends upon the particular application and design constraints imposed on the overall system. Skilled artisans may implement the described functionality in varying ways for each particular application, but such implementation decisions should not be interpreted as causing a departure from the scope or spirit of the present disclosure.

For example, for a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described therein, or a combination thereof. With software, the implementation may be through modules (e.g., procedures, functions, etc.) that perform the functions described therein. The software codes may be stored in memory units and executed by a processor unit. Additionally, the various illustrative flow diagrams, logical blocks, modules and/or algorithm steps described herein may also be coded as computer-readable instructions carried on any computer-readable medium known in the art or implemented in any computer program product known in the art.

In one or more examples, the steps or functions described herein may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

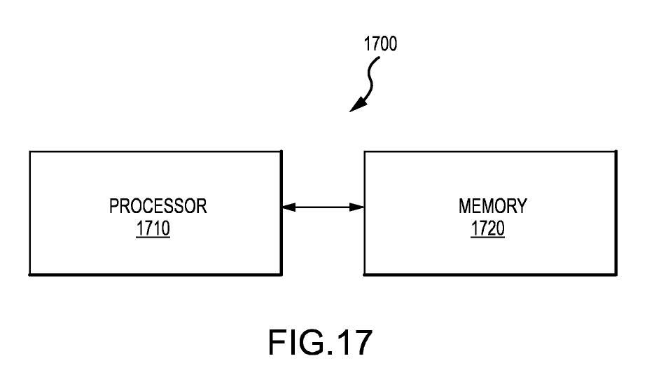

In one example, the illustrative components, flow diagrams, logical blocks, modules and/or algorithm steps described herein are implemented or performed with one or more processors. In one aspect, a processor is coupled with a memory which stores data, metadata, program instructions, etc. to be executed by the processor for implementing or performing the various flow diagrams, logical blocks and/or modules described herein. FIG. 17 illustrates an example of a device 1700 comprising a processor 1710 in communication with a memory 1720 for executing the processes for providing a coding scheme for efficient interference cancellation in a broadcasting network. In one example, the device 1700 is used to implement the algorithm illustrated in FIG. 16. In one aspect, the memory 1720 is located within the processor 1710. In another aspect, the memory 1720 is external to the processor 1710. In one aspect, the processor includes circuitry for implementing or performing the various flow diagrams, logical blocks and/or modules described herein.

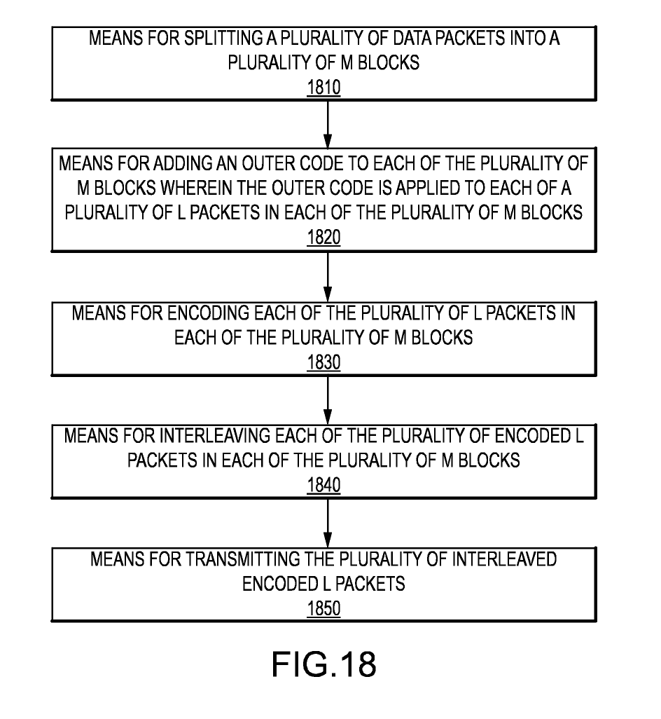

FIG. 18 illustrates an example of a device 1800 suitable for providing a coding scheme for efficient interference cancellation in a broadcasting network. In one aspect, the device 1800 is implemented by at least one processor comprising one or more modules configured to provide different aspects of providing a coding scheme for efficient interference cancellation in a broadcasting network as described herein in blocks 1810, 1820, 1830, 1840 and 1850. For example, each module comprises hardware, firmware, software, or any combination thereof. In one aspect, the device 1800 is also implemented by at least one memory in communication with the at least one processor.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the spirit or scope of the disclosure.

1. A method for providing a coding scheme for interference cancellation in a broadcasting network comprising:
splitting a plurality of data packets into a plurality of M blocks, wherein each of the plurality of M blocks comprises a plurality of L packets;
adding an outer code to each of the plurality of M blocks, wherein the outer code is applied to each of the plurality of L packets in each of the plurality of M blocks;
encoding each of the plurality of L packets which have been outer coded to generate a plurality of encoded L packets in each of the plurality of M blocks; and
interleaving each of the plurality of encoded L packets to generate a plurality of interleaved encoded L packets in each of the plurality of M blocks.

2. The method of claim 1 further comprising broadcasting the plurality of the interleaved encoded L packets to at least one mobile user device.

3. The method of claim 1 wherein the outer code is one of the following: a single parity check code or a Reed-Solomon code.

4. The method of claim 1 wherein the outer code is a block code.

5. The method of claim 4 wherein turbo coding is used for encoding each of the plurality of L packets.

6. The method of claim 4 wherein a low density parity check (LDPC) code is used for encoding each of the plurality of L packets.

7. The method of claim 4 wherein a block code is used for encoding each of the plurality of L packets.

8. The method of claim 7 wherein each of the plurality of encoded L packets within one of the plurality of M blocks passes through a different interleaver.

9. The method of claim 2 wherein the plurality of interleaved encoded L packets is transmitted on a venuecast waverform.

10. The method of claim 9 wherein the venuecast waveform includes one or more of the following features: a QPSK modulation, at least one waveform parameter that is the same as that of a FLO waveform, a plurality of scrambled bits, a service availability signaling using position pilot channel (PPC), or an overhead signal.

11. An apparatus for providing a coding scheme for interference cancellation in a broadcasting network comprising a processor and a memory, the memory containing program code executable by the processor for performing the following:
splitting a plurality of data packets into a plurality of M blocks, wherein each of the plurality of M blocks comprises a plurality of L packets;
adding an outer code to each of the plurality of M blocks, wherein the outer code is applied to each of the plurality of L packets in each of the plurality of M blocks;
encoding each of the plurality of L packets which have been outer coded to generate a plurality of encoded L packets in each of the plurality of M blocks; and
interleaving each of the plurality of encoded L packets to generate a plurality of interleaved encoded L packets in each of the plurality of M blocks.

12. The apparatus of claim 11 wherein the memory further comprising program code for broadcasting the plurality of the interleaved encoded L packets to at least one mobile user device.

13. The apparatus of claim 11 wherein the outer code is one of the following: a single parity check code or a Reed-Solomon code.

14. The apparatus of claim 11 wherein the outer code is a block code.

15. The apparatus of claim 14 wherein the memory further comprising program code for using turbo coding for encoding each of the plurality of L packets.

16. The apparatus of claim 14 wherein a low density parity check (LDPC) code is used for encoding each of the plurality of L packets.

17. The apparatus of claim 14 wherein a block code is used for encoding each of the plurality of L packets.

18. The apparatus of claim 17 wherein the memory further comprising program code for passing each of the plurality of encoded L packets within one of the plurality of M blocks through a different interleaver.

19. The apparatus of claim 12 wherein the plurality of interleaved encoded L packets is transmitted on a venuecast waverform.

20. The apparatus of claim 19 wherein the venuecast waveform includes one or more of the following features: a QPSK modulation, at least one waveform parameter that is the same as that of a FLO waveform, a plurality of scrambled bits, a service availability signaling using position pilot channel (PPC), or an overhead signal.

21. An apparatus for providing a coding scheme for interference cancellation in a broadcasting network comprising:
means for splitting a plurality of data packets into a plurality of M blocks, wherein each of the plurality of M blocks comprises a plurality of L packets;
means for adding an outer code to each of the plurality of M blocks, wherein the outer code is applied to each of the plurality of L packets in each of the plurality of M blocks;
means for encoding each of the plurality of L packets which have been outer coded to generate a plurality of encoded L packets in each of the plurality of M blocks; and
means for interleaving each of the plurality of encoded L packets to generate a plurality of interleaved encoded L packets in each of the plurality of M blocks.

22. The apparatus of claim 21 further comprising means for broadcasting the plurality of the interleaved encoded L packets to at least one mobile user device.

23. The apparatus of claim 21 wherein the outer code is one of the following: a single parity check code or a Reed-Solomon code.

24. The apparatus of claim 21 wherein the outer code is a block code.

25. The apparatus of claim 24 wherein a turbo code is used by the means for encoding each of the plurality of L packets.

26. The apparatus of claim 24 wherein a low density parity check (LDPC) code is used by the means for encoding each of the plurality of L packets.

27. The apparatus of claim 24 wherein a block code is used by the means for encoding each of the plurality of L packets.

28. The apparatus of claim 27 further comprising means for passing each of the plurality of encoded L packets within one of the plurality of M blocks through a different interleaver.

29. The apparatus of claim 22 wherein the plurality of interleaved encoded L packets is transmitted on a venuecast waverform.

30. The apparatus of claim 29 wherein the venuecast waveform includes one or more of the following features: a QPSK modulation, at least one waveform parameter that is the same as that of a FLO waveform, a plurality of scrambled bits, a service availability signaling using position pilot channel (PPC), or an overhead signal.

31. A computer-readable medium storing a computer program, wherein execution of the computer program is for:
splitting a plurality of data packets into a plurality of M blocks, wherein each of the plurality of M blocks comprises a plurality of L packets;
adding an outer code to each of the plurality of M blocks, wherein the outer code is applied to each of the plurality of L packets in each of the plurality of M blocks;
encoding each of the plurality of L packets which have been outer coded to generate a plurality of encoded L packets in each of the plurality of M blocks; and
interleaving each of the plurality of encoded L packets to generate a plurality of interleaved encoded L packets in each of the plurality of M blocks.

32. The computer-readable medium of claim 31 wherein execution of the computer program is also for broadcasting the plurality of the interleaved encoded L packets to at least one mobile user device.
